(19) United States
(12) Patent Application Publication
(10) Pub. No.: US 2012/0112180 A1
(43) Pub. Date: May 10, 2012

(54) METAL OXIDE THIN FILM TRANSISTOR AND MANUFACTURING METHOD THEREOF

(75) Inventors: HSIAO-WEN ZAN, HSINCHU COUNTY (TW); CHUANG-CHUANG TSAI, TAIPEI CITY (TW); WEI-TSUNG CHEN, NANTOU COUNTY (TW); HSIU-WEN HSUEH, TAICHUNG CITY (TW)

(73) Assignee: NATIONAL CHIAO TUNG UNIVERSITY, HSINCHU CITY (TW)

(21) Appl. No.: 12/958,593

(22) Filed: Dec. 2, 2010

(30) Foreign Application Priority Data
Nov. 5, 2010 (TW) 99138224

(51) Int. Cl. H01L 29/786; H01L 21/44

(52) U.S. Cl. 257/43; 438/104; 257/E29.296; 257/E21.476

(57) ABSTRACT

The instant disclosure relates to a metal oxide thin film transistor having a threshold voltage modification layer. The thin film transistor includes a gate electrode, a dielectric layer formed on the gate electrode, an active layer formed on the dielectric layer, a source electrode and a drain electrode disposed separately on the active layer, and a threshold voltage modulation layer formed on the active layer in direct contact with the back channel of the transistor. The threshold voltage modulation layer and the active layer have different work functions so that the threshold voltage modulation layer modulates the threshold voltage of devices and improve the performance of the transistor.

### BACKGROUND OF THE INVENTION

1. Field of the Invention

The instant disclosure relates to a transistor and manufacturing method thereof; in particular, to a metal oxide thin film transistor and manufacturing method thereof.

2. Description of the Related Art

Wide bandgap semiconductor materials have excellent current driving capabilities. Once fully-developed, this technology can be applied in a wide range of devices that require high carrier mobility, such as flat screens displays.

Indium gallium zinc oxide, or InGaZnO (IGZO), is a type of amorphous oxide semiconductor material that receives much attention recently particularly because of its exhibition of high electron mobility (more than 10 cm²/Vs) even under the conditions of room-temperature deposition process. Therefore, IGZO is well suitable for the development of high efficiency electronic devices under low temperature manufacturing conditions. The unique characters such as better flexibility, visible light transparency, large-area uniform deposition at low temperature, and high carrier mobility makes amorphous InGaZnO (a-IGZO) a favorable choice for being the active layer in a thin-film transistor (TFT). The TFT having an active layer made of thin a-IGZO film has carrier mobility greater than that of a conventional hydrogenated amorphous-silicon thin-film transistor (a-Si:H TFT), and the associated uniformity of device array is better than the low temperature polycrystalline silicon TFTs (i.e., LIPS TFT). In addition, because a-IGZO thin film can be fabricated under low temperature, the a-IGZO thin film transistor has the potential to replace a-Si: H TFT and LIPS TFT as the active matrices in the active-matrix organic light-emitting displays (AMOLED).

However, because the hole transport capability of the metal oxide semiconductor is often less-than-ideal, a inverter comprised of complementary-metal-oxide-semiconductor (CMOS) is difficult to be realized. Only through the use of the transistors having threshold voltage difference are we able to form the basic inverter units on a logic circuit. Conventionally, the threshold voltage of the MOSFET is dictated by the dopant concentration in the active layer. However, the modification of dopant concentration in the active layer often causes negative impact on the characteristics of the transistor such as carrier mobility, subthreshold swing, and current leakage. Another conventional method employs double-gate arrangement to produce dual channels for improving the characteristics of the transistor. However, the fabrication of double gate electrodes is more complicated and expensive.

Therefore, how to effectively control the threshold voltage of the device and not inducing negative effects are the main emphasis of the current research.

### SUMMARY OF THE INVENTION

The exemplary embodiment of the instant disclosure provides a metal oxide thin film transistor, which comprises a gate electrode, a dielectric layer disposed on the gate electrode, an active layer disposed on the dielectric layer, a source electrode and a drain electrode spaced on the active layer, and a threshold voltage modulation layer formed on the back channel of the transistor. The threshold voltage modulation layer and the active layer have an appropriate work function difference.

The exemplary embodiment of the instant disclosure also provides a manufacturing method of the metal oxide thin film transistor. The manufacturing method includes the steps of: providing a substrate; fabricating a metal oxide thin film transistor on the substrate, where the metal oxide thin film transistor comprises at least a gate electrode, a dielectric layer, an active layer, and source and drain electrodes; and fabricating a threshold voltage modulation layer on the back channel of the metal oxide thin film transistor, where the threshold voltage modulation layer and the active layer have an appropriate work function difference.

The instant disclosure has the following advantages. The instant disclosure mainly involves floatingly disposing the threshold voltage modulation layer on the active layer, where the work function difference between the two layers creates a body effect, for adjusting and controlling the threshold voltage of the device. Next, the fabrication and structure of the threshold voltage modulation layer do not negatively affect the characteristics of the device, but can rather increase the electron mobility of the device significantly.

In order to further appreciate the characteristics and technical contents of the instant disclosure, references are hereunder made to the detailed descriptions and appended drawings in connection with the instant disclosure. However, the appended drawings are merely shown for exemplary purposes, rather than being used to restrict the scope of the instant disclosure.

### BRIEF DESCRIPTION OF THE DRAWINGS

FIG. 1 shows a schematic view of a metal oxide thin film transistor of the first embodiment of the instant disclosure.

FIG. 2a shows a schematic view of a metal oxide thin film transistor of the second embodiment of the instant disclosure.

FIG. 2b shows a schematic view of a metal oxide thin film transistor of the third embodiment of the instant disclosure.

FIG. 2c shows a schematic view of a metal oxide thin film transistor of the fourth embodiment of the instant disclosure.

FIG. 3 shows a graph comparing the characteristics between the conventional transistor and the metal oxide thin film transistor having the gold threshold voltage modulation layer of the instant disclosure.

FIG. 4 shows a graph illustrating the change of the threshold voltage based on different materials of the threshold voltage modulation layer of the instant disclosure.

FIG. 5 shows a graph illustrating the increase of electron mobility based on different materials of the threshold voltage modulation layer of the instant disclosure.

### DETAILED DESCRIPTION OF THE PREFERRED EMBODIMENTS

The instant disclosure provides a metal oxide transistor having a threshold voltage modulation layer and the manufacturing method thereof. Particularly, the method of the instant disclosure does not require additional construction of dielectric layers and electrodes. Rather, a material having an appropriate work function is employed in direct contact with the active layer to achieve the modulation of the gate electrode. The threshold voltage modulation layer may significantly increase the carrier mobility of the transistor device without causing undesirable current leakage problems.

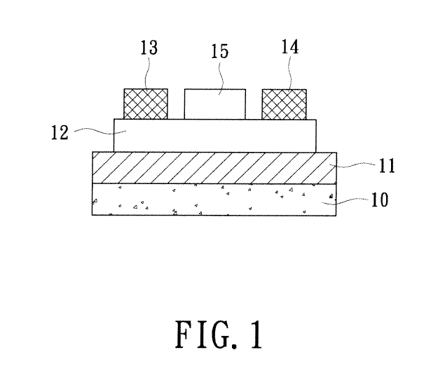

Please refer to FIG. 1, which shows the overall construction of the transistor according to the instant disclosure. The manufacturing method of the metal oxide thin film transistor of the instant disclosure will be discussed as follows.

First, a substrate (not shown) is provided. The substrate can be a glass substrate or a plastic thin film substrate, such as polyimide substrate, polycarbonate substrate, polyethylene terephthalate (PET) thin film substrate, or even stainless steel substrate coated with insulating layers. Person skilled in the art shall understand that the choice of the substrate is not restricted to the list above.

Referring to FIG. 1, the next step involves the formation of a metal oxide thin film transistor on the substrate. The metal oxide thin film transistor includes at least a gate electrode 10, a dielectric layer 11, an active layer 12, a source electrode 13, and a drain electrode 14. Since the instant disclosure is applicable to a variety of transistors, the exemplary embodiment is discussed based on the bottom gate electrode and the top source and drain electrodes of the transistor. The following descriptions such as “on top of” or “under” are based on the bottom gate electrode and the top source and drain electrodes of the transistor. However, the descriptions are not used to restrict the scope of the instant disclosure.

First, a gate electrode 10 is formed on the substrate by methods including sputtering deposition, pulsed laser deposition (PLD), electron beam deposition, or chemical vapor deposition (CVD). Any electrode material having good conductivity may be used for the gate electrode 10. Some example of such materials including titanium (Ti), platinum (Pt), gold (Au), nickel (Ni), aluminum (Al), molybdenum (Mo) and the alloy or thin film thereof, or indium tin oxide (ITO) and other oxidized conductors.

Next, photolithography process or other suitable methods is carried out on the gate electrode 10 to form the desired pattern. The dielectric layer 11 (i.e., gate electrode insulating layer) is then formed on the gate electrode patterns. The dielectric layer 11 can be formed by deposition techniques including sputtering deposition, pulsed laser deposition (PLD), electron beam deposition, and plasma-enhanced chemical vapor deposition (PECVD). Any material having excellent insulating property can be used to form the dielectric layer 11, and such material includes silicon oxide film or silicon nitride film formed by PECVD or sputtering deposition.

Next, the active layer 12 is formed on the dielectric layer 11. In the present step, the active layer 12 made of oxidized film is formed on the dielectric layer 11. The active layer 12 can be an oxidized semiconductor, such as a metal oxide active layer. Specifically, the active layer 12 can be fabricated by methods including sputtering deposition, pulsed laser deposition, electron beam deposition, or sol-gel process.

For example, the formation of the active layer 12 may be carried out by employing a RF magnetron sputtering deposition process to deposit gallium zinc oxide (ZnO:Ga; 97/3 wt %; 99.995% purity, abbreviated as GZO) thin film on the dielectric layer 11 in a pure argon gas sputtering environment. Alternatively, co-precipitation (CPT) method may be applied to three types of salt substances: indium nitrate [In(NO₃)₃], gallium trichloride [GaCl₃], and zinc nitrate [Zn(NO₃)₂], along with two types of alkaline substances: sodium hydroxide [NaOH] and ammonium hydroxide [NH₄OH]. Then, the precipitates and solvents undergo hydrothermal or calcination treatment to produce IGZO gel. The IGZO gel is coated onto the dielectric layer 11 to form amorphous InGaZnO (a-IGZO) thin film as the active layer 12. Other options include tin indium zinc (Sn—In—Zn) oxide, indium zinc gallium magnesium (In—Zn—Ga—Mg) oxide, indium (In) oxide, indium tin (In—Sn) oxide, indium gallium (In—Ga) oxide, indium zinc (In—Zn) oxide, or zinc gallium (Zn—Ga) oxide, etc. The abovementioned materials are for exemplary purposes only, rather than being used to restrict the scope of the instant disclosure.

Next, the source electrode 13 and the drain electrode 14 are formed separately on the active layer 12 with a predetermined distance there-between. Specifically, a diffusion process or other suitable techniques may be used to lower the resistance at the respective sides of the active layer 12 to form the source region and the drain region. Then, the source electrode 13 and drain electrode 14 may be respectively formed on the source and the drain regions by methods including sputtering deposition, pulsed laser deposition (PLD), electron beam deposition, or chemical vapor deposition (CVD). The electrode material can be metallic material with excellent conductivity, such as titanium (Ti), platinum (Pt), gold (Au), nickel (Ni), aluminum (Al), molybdenum (Mo), any alloy of listed materials, thin film, oxidized conductor like ITO, or gold layered electrode material.

Next, a threshold voltage modulation layer 15 is disposed on the back channel of the metal oxide thin film transistor. Particularly, a material having work function difference from the active layer 12 is selected and disposed on the active layer 12 in direct contact with the back channel of the transistor. It is observed that the threshold voltage modulation layer 15, which is in direct contact with the active layer 12, can effectively modify the threshold voltage of the transistor.

The following exemplary embodiment explores the beneficial effects of the threshold voltage modulation layer 15. The metallic layer is formed by the deposition methods including the sputtering techniques discussed above and floatingly disposed on the back channel of the active layer 12 of the metal oxide thin film transistor. The variation in threshold voltage is then measured for comparison.

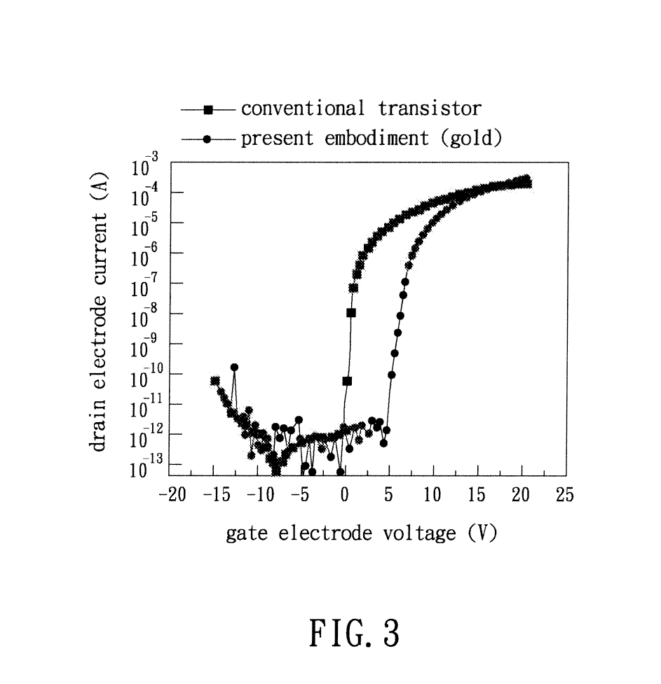

Please refer to FIG. 3 and Table 1, which illustrate the change in characteristics between a conventional transistor and a metal oxide thin film transistor having a gold (Au) threshold voltage modulation layer 15 according to the instant disclosure.

TABLE 1

| | Δ VT | Δ Von | VT | Von | μ(cm²/ | S.S. | |
|---|---|---|---|---|---|---|---|
| | (V) | (V) | (V) | (V) | Vs) | (V/dec) | on/off |
| Conventional | — | — | 2.4 | −0.6 | 9.24 | 0.28 | 3.5E8 |
| Instant | 5.5 | 4.9 | 7.9 | 4.2 | 22.8 | 0.39 | 4.5E8 |
| Disclosure | | | | | | | |

Based on the results from FIG. 3 and Table 1, the metal oxide thin film transistor having a gold threshold voltage modulation layer 15 has a threshold voltage of 5.5V higher in comparison to the conventional transistor. Also, the carrier mobility μ has increased significantly from 9.24 cm²/Vs of the conventional transistor to 22.8 cm²/Vs. Thus, it is shown that the instant disclosure can significantly improve the capabilities of the transistor. Moreover, the metal oxide thin film transistor having the gold threshold voltage modulation layer 15 does not exhibit undesirable side effects and meets the standard requirements.

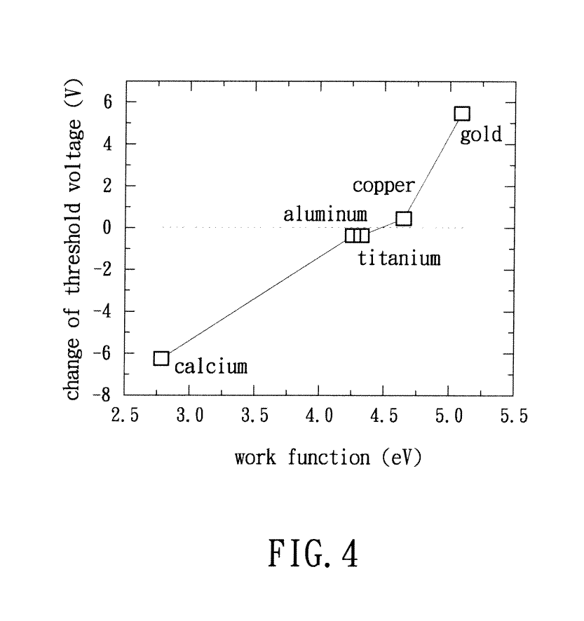

Please refer to FIG. 4, which explores the choices of materials for the threshold voltage modulation layer 15. It is shown that the threshold voltage of the transistor can be achieved within the range of +/−6V if the work function of the threshold voltage modulation layer is maintained between 2.9 (calcium) and 5.1 (gold) Thus, the material selection for the threshold voltage modulation layer 15 should base on the work function of the materials. The ideal choice for such materials is therefore not limited to metal only but may also include oxides.

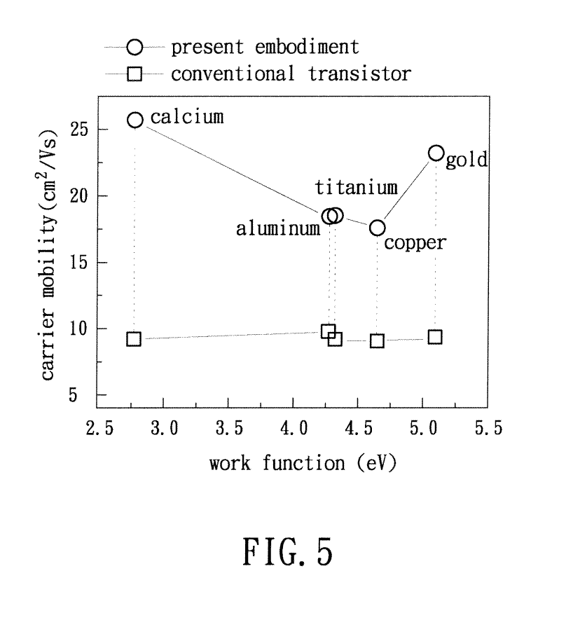

Experiment results indicate that, as shown in FIGS. 4 and 5, the selection of aluminum (Al), titanium (Ti), and copper (Cu) as the threshold voltage modification layer produces identical level of increase in carrier mobility. Specifically, a titanium (Ti) modification layer can increase the carrier mobility from 10 to 20 cm²/Vs. Thus, proper selection of material for the threshold voltage modulation layer 15 can effectively improve the characteristics of the transistor.

The experimental results of the instant disclosure show strong correlations between the threshold voltage of the transistor and the work function of the modulation layer 15. Moreover, it may infer that the modifying effect of the threshold voltage in the transistor is attributed to the charge separation during coupling between the active layer 12 and the threshold voltage modulation layer 15.

Based on the above discussion, the instant disclosure provides a method for fabricating a metal oxide thin film transistor, which comprises: a, a dielectric layer 11 disposed on the gate electrode 10, an active layer 12 disposed on the dielectric layer 11, a source electrode 13 and a drain electrode 14 separately disposed on the active layer 12, and a threshold voltage modulation layer 15 disposed in direct contact with the back channel of the transistor, where the threshold voltage modulation layer 15 and the active layer 12 have different work functions. Specifically, the threshold voltage modulation layer 15 disposed on the active layer 12 is regarded as a floating electrode, e.g., “floating” means that the threshold voltage modulation layer 15 is not serving as an electrode, thus creating a body effect between the two layers for adjusting the threshold voltage and/or increasing the carrier mobility of the device.

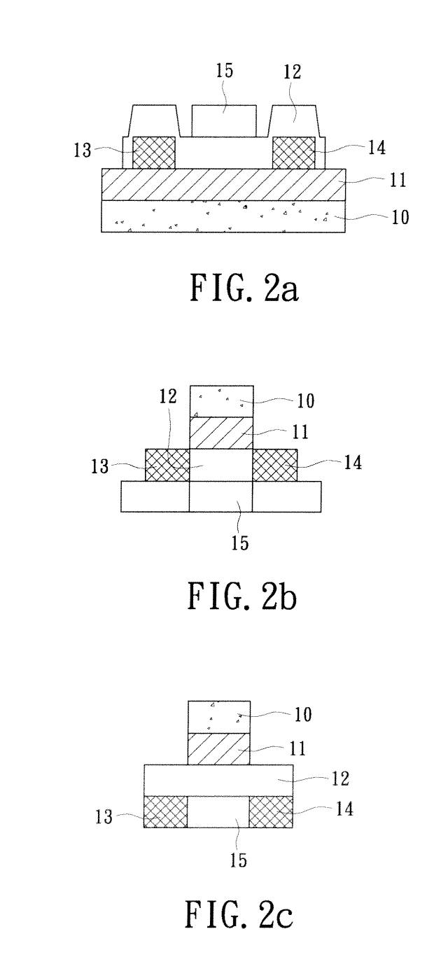

On the other hand, the threshold voltage modulation layer 15 can be used with a variety of transistors, such as the bottom gate electrode/bottom source and drain electrodes structure in FIG. 2a, the top gate electrode/top source and drain electrodes structure in FIG. 2b, or the top gate electrode/bottom source and drain electrodes in FIG. 2c, and etc.

Based on the above discussions, the instant disclosure has the following advantages. First, the instant disclosure uses a threshold voltage modulation layer having a different work function from the active layer to contact directly to the active layer, for upgrading the capabilities of the device and adjusting the associated threshold voltage. Based on the planned change of the threshold voltage, a threshold voltage modulating layer having an appropriate work function difference with the active layer can be chosen. In addition, the threshold voltage modulation layer of the instant disclosure can perform simple functional upgrade, such as increasing the carrier mobility, while maintaining similar threshold voltage simultaneously.

Secondly, the threshold voltage modulation layer of the instant disclosure does not induce negative effect on the device. For example, after adding the threshold voltage modulation layer, the addition would not increase current leakage or threshold swing. Therefore, the addition can upgrade the functional characteristics of various conventional transistors. Furthermore, the instant disclosure is able to adjust the threshold voltage, which allows conventional transistors to be more applicable for electro-optical displays and logic circuits, etc.

Thirdly, the manufacturing method of the instant disclosure is simple and does not require fabricating additional electrodes (the threshold voltage modulation layer of the instant disclosure is a floating connection structure, not an electrode), therefore does not raise the manufacturing difficulty.

The descriptions illustrated supra set forth simply the preferred embodiments of the instant disclosure; however, the characteristics of the instant disclosure are by no means restricted thereto. All changes, alternations, or modifications conveniently considered by those skilled in the art are deemed to be encompassed within the scope of the instant disclosure delineated by the following claims.

What is claimed is:

1. A metal oxide thin film transistor, comprising:
a gate electrode;
a dielectric layer disposed on the gate electrode;
an active layer disposed on the dielectric layer;
a source electrode and a drain electrode separately formed on the active layer; and
a threshold voltage modulation layer disposed on the active layer in direct contact with the back channel of the transistor, wherein the threshold voltage modulation layer and the active layer have an different work functions.

2. The metal oxide thin film transistor of claim 1, wherein the threshold voltage modulation layer is a metallic layer.

3. The metal oxide thin film transistor of claim 1, wherein the threshold voltage modulation layer has a work function ranging from 2.9 to 5.1.

4. The metal oxide thin film transistor of claim 1, wherein the active layer is an oxidized metallic substance.

5. The metal oxide thin film transistor of claim 1, wherein the threshold voltage modulation layer is floatingly formed on the back channel.

6. A manufacturing method of metal oxide thin film transistor, comprising the steps of:
providing a substrate;
fabricating a metal oxide thin film transistor on the substrate, the metal oxide thin film transistor comprising at least a gate electrode, a dielectric layer, an active layer, a source electrode, and a drain electrode; and
fabricating a threshold voltage modulation layer on the active layer in direct contact with the back channel of the metal oxide thin film transistor, wherein the threshold voltage modulation layer and the active layer have different work functions.

7. The manufacturing method of metal oxide thin film transistor of claim 6, wherein for the step of fabricating the threshold voltage modulation layer, the threshold voltage modulation layer is a metallic layer.

8. The manufacturing method of metal oxide thin film transistor of claim 6, wherein for the step of fabricating the threshold voltage modulation layer, the work function range of the threshold voltage modulation layer is between 2.9 and 5.1.

9. The manufacturing method of metal oxide thin film transistor of claim 6, wherein for the step of fabricating the threshold voltage modulation layer, the threshold voltage modulation layer is floatingly formed on the back channel of the metal oxide thin film transistor.

10. The manufacturing method of metal oxide thin film transistor of claim 6, wherein for the step of fabricating the metal oxide thin film transistor, the active layer is an oxidized metallic substance.
